(19) United States
(12) Patent Application Publication
(10) Pub. No.: US 2008/0308307 A1
(43) Pub. Date: Dec. 18, 2008

(54) TRACE STRUCTURE AND METHOD FOR FABRICATING THE SAME

(75) Inventors: Jui-Hsien Chang, Hsinchu County (TW); Chi-Chen Lee, Taipei City (TW); Dyi-Chung Hu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANCED CHIP ENGINEERING TECHNOLOGY INC., Hsinchu County (TW)

(21) Appl. No.: 11/761,381

(22) Filed: Jun. 12, 2007

(51) Int. Cl. H05K 1/09; H05K 3/02

(52) U.S. Cl. 174/257; 29/846

(57) ABSTRACT

A trace structure with a particular profile to eliminate stress concentration and the fabricating method thereof are provided. The trace structure includes a conductive line, a seed layer, and a protection layer, wherein an upper part of the trace line is covered by the protection layer to prevent sharp edges caused by over etching in the fabrication of the conductive line. Hence, the stress concentration due to the sharp edges in the trace structure is diminished and the reliability of packaging structures or other devices applying the trace structure is assured.

### BACKGROUND OF THE INVENTION

1. Field of the Invention

The present invention generally relates to a trace structure of a circuit substrate and a fabricating method thereof. More particularly, the present invention relates to a trace structure having a particular trace profile and a fabricating method to achieve the particular trace profile.

2. Description of Related Art

Semi additive method is widely used to define metal lines in high density electronic packaging. In which, copper (Cu) is the most widely used material to fabricate the metal lines. Furthermore, in order to protect metal lines from corrosion, a protection layer is also formed to cover the metal lines. The most widely used material of the protection layer includes gold (Au), alloy of nickel (Ni)/gold (Au), or tin (Sn).

FIGS. 1A-1C illustrate a conventional fabricating process of a trace structure of a circuit substrate. Referring to FIG. 1A, a base layer 110 with a seed layer 120 formed thereon is provided, and a patterned photoresist layer 130 is formed on the seed layer 120 to expose a part of the seed layer 120. A copper line 140 and a protection layer 150 are sequentially formed over the exposed part of the seed layer 120 by plating through the seed layer 120. Then, as shown in FIG. 1B, the patterned photoresist layer 130 is removed and the other part of the seed layer 120 is exposed. After that, as shown in FIG. 1C, an etching process is conducted by taking the protection layer 150 and the copper line 140 as a mask to remove the other part of the seed layer 120. Then, a dielectric layer 160 is formed on the base layer 110 to cover the protection layer 150, the copper line 140, and the remained seed layer 120.

However, since the seed layer 120 needs to be removed after defining the trace structure in the conventional fabricating process, over etching of the copper line 140 adjacent to the protection layer 150 causes overhang 170 (as shown in FIG. 1C) of the protection layer 150 over the copper line 140.

In particular, for the metal line in a soft dielectric layer, such as silicone based dielectric layer, the sharp edges of the overhang as mentioned above causes stress concentration in the surrounding soft dielectric layer and results in cracks of the soft dielectric layer. This may cause reliability concerns in the long run.

### SUMMARY OF THE INVENTION

Accordingly, the present invention is directed to a trace structure of a circuit substrate, which can eliminate the stress concentration caused by the sharp edges of the protective layer, and thus provides superior reliability. Furthermore, the present invention is also directed to a method for fabricating the trace structure.

As embodied and broadly described herein, the present invention provides a trace structure of a circuit substrate, wherein the circuit substrate comprises a base layer and a dielectric layer, and the trace structure is disposed on the base layer and covered by the dielectric layer. The trace structure comprises a conductive line, a seed layer, and a protection layer, wherein the conductive line is disposed on the base layer, and the conductive line comprises an upper part and a lower part located between the upper part and the base layer. The upper part has a top surface and two side surfaces connecting to the top surface. In addition, a width of the lower part decreases gradually from a location close to the base layer towards the upper part. The seed layer is disposed between the conductive line and the base layer. The protection layer is disposed on the upper part of the conductive line for covering the top surface and both the side surfaces of the upper part.

According to an embodiment of the present invention, the lower part of the conductive line has a trapezoidal cross-section.

According to an embodiment of the present invention, the material of the conductive line comprises copper.

According to an embodiment of the present invention, the material of the protection layer comprises gold (Au), alloy of nickel (Ni)/gold (Au), or tin (Sn).

The present invention further provides a method for fabricating a trace structure. The method comprises providing a base layer; forming a seed layer on the base layer; forming a patterned mask layer on the seed layer for exposing a part of the seed layer; forming a conductive line on the exposed part of seed layer by performing a plating process through the seed layer, wherein the conductive line has a top surface and two side surfaces connecting to the top surface; removing a part of the patterned mask layer adjacent to the conductive line for exposing a part of each side surface of the conductive line; forming a protection layer covering the top surface and the exposed part of each side surface of the conductive line; removing the patterned mask layer; performing an etching process to the seed layer by taking the protection layer and the conductive line as a mask to remove a part of the seed layer; and, forming a dielectric layer on the base layer to cover the protection layer, the conductive line and the remained seed layer.

According to an embodiment of the present invention, the material of the patterned mask layer comprises photoresist.

According to an embodiment of the present invention, the method of removing the part of the patterned mask layer comprises performing a dry etching process or a wet etching process to the patterned mask layer.

According to an embodiment of the present invention, the method of forming the protection layer comprises performing a plating process.

According to an embodiment of the present invention, the etching process for removing the part of the seed layer comprises a wet etching process.

Accordingly, a trace structure with particular the profile and the fabricating method thereof are proposed in the present invention to remove sharp edges of the protection layer formed in the conventional trace structure. Hence, the stress concentration in the trace structure is diminished and the reliability thereof is improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1C illustrate a conventional fabricating process of a trace structure in sequence.

FIG. 2 illustrates a trace structure of a circuit substrate according to an embodiment of the present invention.

FIGS. 3A-3F illustrate a fabricating process of a trace structure in sequence

according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

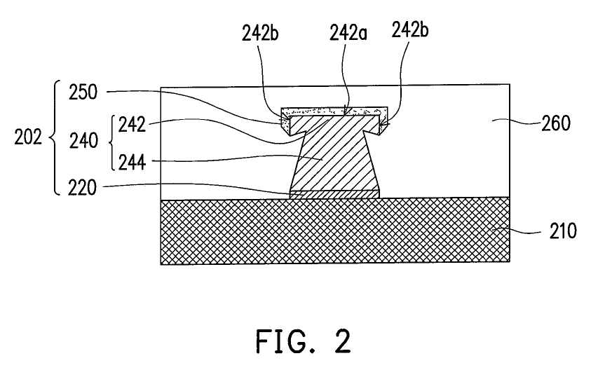

FIG. 2 illustrates a trace structure of a circuit substrate according to an embodiment of the present invention. As shown in FIG. 2, the trace structure 202 is fabricated on a base layer 210 and covered by a dielectric layer 260. The base layer 210 can be any types of semi-finished substrate, such as a single-layered substrate or a multi-layered substrate. In addition, the dielectric layer 260 may be made of a soft dielectric material such as a silicone based material, or other applicable dielectric materials.

The trace structure 202 comprises a conductive line 240, a seed layer 220, and a protection layer 250. The conductive line 240 is disposed on the base layer 210 and comprises an upper part 242 and a lower part 244, wherein the lower part 244 is located between the upper part 242 and the base layer 210. The material of the conductive line 240 may comprise metal such as copper, or other applicable conductive material. In addition, the seed layer 220 is disposed between the base layer 210 and the conductive line 240. The protection layer 250 is disposed on the conductive line 240 to cover the upper part 242 of the conductive line 240. The material of the protection layer 250 may comprise metal such as gold (Au), alloy of nickel (Ni)/gold (Au), or tin (Sn), or other applicable conductive material which can effectively preserve the conductive line 240 from corrosion.

More specifically, the protection layer 250 is disposed on a top surface 242a and both side surfaces 242b of the upper part 242. Furthermore, the lower part 244 of the conductive line 240 may take a tapered shape caused by the over etching in the fabrication of the conductive line 240. In other words, a width of the lower part 244 decreases gradually from a location close to the base layer 210 towards the upper part 242. In this embodiment, the lower part 244 of the conductive line 240 has a trapezoidal cross-section.

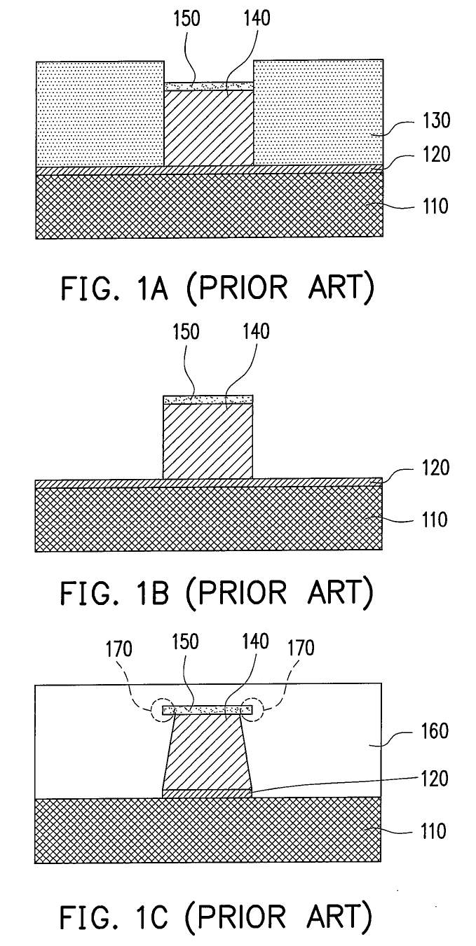

According to the aforementioned embodiment, since at least the upper part 242 is covered by the protection layer 250, the over etching of the conductive line 240 is restricted to the lower part 244, while the upper part 242 is preserved from being etched. Therefore, the overhang 170 caused by the over etching of the copper line 140 adjacent to the protection layer 150 in the conventional trace structure as shown in FIG. 1C can be prevented. The stress concentration due to the sharp edges of trace structure can be eliminated, and thus the reliability thereof is assured.

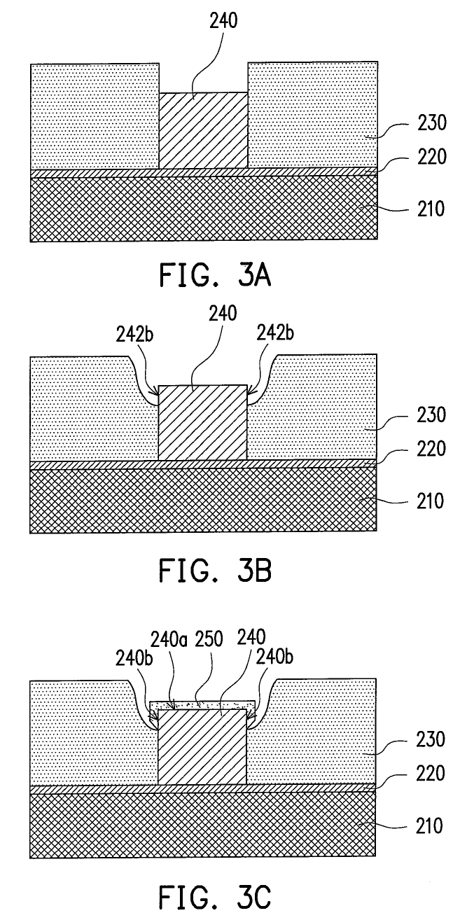

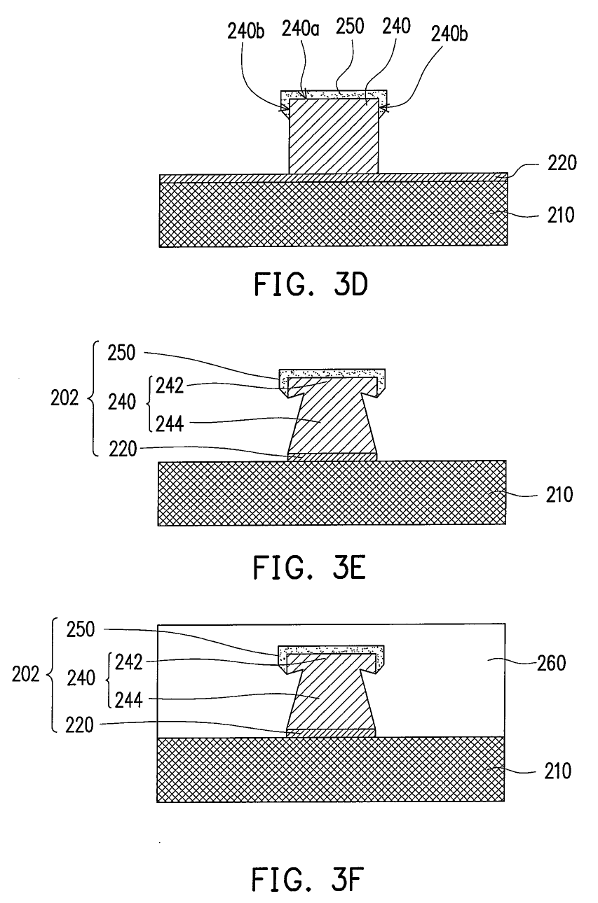

A method suitable for fabricating the aforementioned trace structure 202 is further described with reference to the following embodiment. FIGS. 3A-3F illustrate a fabricating process of a trace structure in sequence according to an embodiment of the present invention.

As shown in FIG. 3A, the base layer 210 is firstly provided, and the seed layer 220 is formed on the base layer 210 by, for example, electroless plating or other applicable deposition manners. Then, a patterned mask layer 230 is provided on the seed layer 220 for exposing a part of the seed layer 220, and the conductive line 240 is formed on the exposed part of seed layer 220 by performing a plating process through the seed layer 220. The patterned mask layer 230 may be a photoresist layer which can be patterned by performing a lithography process.

Then, as shown in FIG. 3B, a part of the patterned mask layer 230 adjacent to the conductive line 240 is removed to expose a part of each side surface 240b of the conductive line 240. The part of the patterned mask layer 230 can be removed by performing, for example, a dry etching process or a wet etching process.

Thereafter, as shown in FIG. 3C, the protection layer 250 is formed on the conductive line 240 by, for example, plating, to cover the top surface 240a and the exposed part of each side surface 240b of the conductive line 240. Then, the patterned mask layer 230 is removed, as shown in FIG. 3D.

Next, referring to FIG. 3E, an etching process is performed by using the protection layer 250 and the conductive line 240 as an etching mask, so as to remove the seed layer 220 exposed by the conductive line 240 and to form the trace structure 202 comprising the protection layer 250, the conductive line 240 and the remained seed layer 220. The etching process performed in FIG. 3E may be a wet etching process. Since at least the upper part 242 of the conductive line 240 is covered by the protection layer 250, the over etching of the conductive line 240 as performing the etching process is restricted to the lower part 244 of the conductive line 240, while the upper part 242 is preserved from being etched. Then, as shown in FIG. 3F, the dielectric layer 260 is formed on the base layer 210 to cover the trace structure 202.

In summary, a trace structure with a particular profile and the fabricating method thereof are proposed in the present invention, wherein the upper part of the trace line is covered by the protection layer to prevent sharp edges caused by the over etching in the fabrication of the conductive line. Hence, the stress concentration in the trace structure is diminished and the reliability of packaging structures or other devices applying the trace structure is assured. Furthermore, performance of drop test to the devices applying the trace structure is also enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A trace structure of a circuit substrate, wherein the circuit substrate comprises a base layer and a dielectric layer, and the trace structure is disposed on the base layer and covered by the dielectric layer, the trace structure comprising:
a conductive line, disposed on the base layer, wherein the conductive line comprises an upper part and a lower part located between the upper part and the base layer, the upper part has a top surface and two side surfaces connecting to the top surface, and a width of the lower part decreases gradually from a location close to the base layer towards the upper part;
a seed layer, disposed between the conductive line and the base layer; and
a protection layer, disposed on the upper part of the conductive line for covering the top surface and both the side surfaces of the upper part.

2. The trace structure according to claim 1, wherein the lower part of the conductive line has a trapezoidal cross-section.

3. The trace structure according to claim 1, wherein the material of the conductive line comprises copper.

4. The trace structure according to claim 1, wherein the material of the protection layer comprises gold (Au), alloy of nickel (Ni)/gold (Au), or tin (Sn).

5. A method for fabricating a trace structure of a circuit substrate, comprising:
providing a base layer;
forming a seed layer on the base layer;
forming a patterned mask layer on the seed layer for exposing a part of the seed layer;
forming a conductive line on the exposed part of seed layer by performing a
plating process through the seed layer, wherein the conductive line has a top surface and two side surfaces connecting to the top surface;
removing a part of the patterned mask layer adjacent to the conductive line for exposing a part of each side surface of the conductive line;
forming a protection layer covering the top surface and the exposed part of each side surface of the conductive line;
removing the patterned mask layer;
performing an etching process to the seed layer by taking the protection layer and the conductive line as a mask to remove a part of the seed layer; and
forming a dielectric layer on the base layer to cover the protection layer, the conductive line and the remained seed layer.

6. The method according to claim 5, wherein the material of the patterned mask layer comprises photoresist.

7. The method according to claim 5, wherein the method of removing the part of the patterned mask layer comprises performing a dry etching process or a wet etching process to the patterned mask layer.

8. The method according to claim 5, wherein the method of forming the protection layer comprises performing a plating process.

9. The method according to claim 5, wherein the etching process for removing the part of the seed layer comprises a wet etching process.
